(19) United States
(12) Patent Application Publication
(10) Pub. No.: US 2004/0026762 A1
(43) Pub. Date: Feb. 12, 2004

(54) Semiconductor device

(75) Inventors: Yuuichi Hirano, Tokyo (JP); Takuji Matsumoto, Tokyo (JP); Takashi Ipposhi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/459,614

(22) Filed: Jun. 12, 2003

(30) Foreign Application Priority Data
Aug. 8, 2002 (JP) 2002-230999

(51) Int. Cl. H01L 29/76; H01L 31/062

(52) U.S. Cl. 257/536; 257/537; 257/538; 257/379; 257/380

(57) ABSTRACT

It is an object to provide a semiconductor device in which a resistance value of a resistor formed by a silicon film is changed with difficulty. A resistor (31) is formed by an amorphous silicon film, and silicides (32a) and (32b) are formed in connecting portions of contact plugs (5a) and (5b) in a surface portion thereof. Since the resistor (31) is the amorphous silicon, a hydrogen atom is bonded with more difficulty as compared with the case in which polycrystalline silicon is used for a material of the resistor. Thus, it is possible to obtain a semiconductor device in which a resistance value of the resistor formed by the silicon film is changed with difficulty. Moreover, the suicides (32a) and (32b) are formed in the connecting portions of the contact plugs (5a) and (5b). Therefore, when contact holes for the contact plugs (5a) and (5b) are to be formed on a first interlayer insulating film (4a) by etching, the resistor (31) is etched with difficulty. Consequently, it is possible to obtain a semiconductor device in which the resistance value of the resistor (31) is changed with more difficulty.

### BACKGROUND OF THE INVENTION

1. Field of the Invention

The present invention relates to a semiconductor device using a silicon film as a resistor.

2. Description of the Background Art

Conventionally, a silicon film such as a polycrystalline silicon film has been employed as a material of a resistor to be formed in a semiconductor device.

FIGS. 38 and 39 are a top view and a sectional view which show a conventional semiconductor device comprising a resistor formed by a polycrystalline silicon film, respectively. In the semiconductor device, a resistor 30 is formed by a polycrystalline silicon film and is provided on an isolating region 2 in a semiconductor substrate 1. Contact plugs 5a and 5b are connected to both ends of a surface of the resistor 30. The contact plugs 5a and 5b are connected to wirings 6a and 6b provided on a first interlayer insulating film 4a, respectively. A second interlayer insulating film 4b is formed on the wirings 6a and 6b.

The semiconductor substrate 1 is a silicon substrate, for example, and the isolating region 2 is formed by a silicon oxide film, for example. Active regions 1a and 1b having an impurity ion implanted at a high concentration are formed on a surface of the semiconductor substrate 1. Moreover, the contact plugs 5a and 5b are formed by tungsten plugs, for example, and the wirings 6a and 6b are formed by aluminum wirings, for example. The first and second interlayer insulating films 4a and 4b are formed by a silicon oxide film, for example.

In MV1 of an enlarged view in FIG. 39, a region AR in the resistor 30 is enlarged. As shown in the MV1 of the enlarged view, a large number of grains GR to be partial single crystal regions are collected in a polycrystalline silicon film. A dangling bond of a silicon atom is present in a grain boundary BS between the grains GR.

In a process for manufacturing a semiconductor device, a semiconductor wafer is exposed to a hydrogen atmosphere in some cases. At this time, a hydrogen atom is easily bonded to the dangling bond of the silicon atom. MV2 of an enlarged view in FIG. 39 shows the easy bonding and a hydrogen atom HY enters the grain boundary BS. When the hydrogen atom HY enters, a resistance value of the resistor 30 is changed and is thus deviated from a design resistance value.

### SUMMARY OF THE INVENTION

It is an object of the present invention to provide a semiconductor device in which a resistance value of a resistor formed by a silicon film is changed with difficulty.

According to a first aspect of the present invention, a semiconductor device includes a resistor formed by a silicon film. At least a surface portion of the resistor is amorphous silicon and a silicide is formed in a connecting portion of a contact plug in the surface portion.

At least the surface portion of the resistor formed by the silicon film is the amorphous silicon. Accordingly, it is possible to obtain a semiconductor device in which a hydrogen atom is introduced with more difficulty and a resistance value of the resistor formed by the silicon film is changed with more difficulty as compared with the case in which polycrystaline silicon is used for a material of the resistor. Moreover, the silicide is formed in the connecting portion of the contact plug in the surface portion of the resistor. Consequently, it is possible to obtain a semiconductor device in which the resistor is etched with difficulty during etching for forming a contact hole and the resistance value of the resistor is changed with more difficulty.

According to a second aspect of the present invention, a semiconductor device includes a resistor formed by a silicon film and a silicon germanium film provided in contact with the resistor.

The silicon germanium film having the function of activating an impurity in the resistor is provided in contact with the resistor. Accordingly, it is possible to reduce a resistance value of the resistor. Thus, it is possible to obtain a semiconductor device in which the resistance value of the resistor formed by the silicon film is changed with difficulty.

According to a third aspect of the present invention, a semiconductor device includes a resistor formed by a silicon film, an interlayer insulating film covering the resistor, and a dummy contact plug formed by a different material from a material of the interlayer insulating film, insulated from the resistor and covering at least a part of an upper portion of the resistor. The different material has the function of preventing a hydrogen atom from entering the resistor.

At least a part of the upper portion of the resistor is formed by the different material from the material of the interlayer insulating film and is covered with the dummy contact plug insulated from the resistor. Since the different material has the function of preventing a hydrogen atom from entering the resistor, it is possible to obtain a semiconductor device in which a resistance value of the resistor formed by the silicon film is changed with difficulty. Moreover, the dummy contact plug is insulated from the resistor. Therefore, the resistance value of the resistor formed by the silicon film is not influenced and the same resistance value is changed with more difficulty.

According to a fourth aspect of the present invention, a semiconductor device includes an SOI (Silicon On Insulator) substrate including a laminating structure having a support substrate, a buried insulating film and a silicon layer, a resistor provided on the SOI substrate and formed by a silicon film, an interlayer insulating film covering the resistor, and a dummy contact plug formed by a different material from a material of the interlayer insulating film in the vicinity of the resistor and penetrating through the buried insulating film and an isolating region formed in the silicon layer. The different material has the function of preventing a hydrogen atom from entering the resistor.

The dummy contact plug is formed by the different material from the material of the interlayer insulating film in the vicinity of the resistor. Since the different material has the function of preventing a hydrogen atom from entering the resistor, it is possible to obtain a semiconductor device in which a resistance value of the resistor formed by the silicon film is changed with difficulty. Moreover, the dummy contact plug penetrates through the buried insulating film of the SOI substrate and the isolating region formed in the silicon layer. Therefore, it is possible to more reliably prevent the hydrogen atom from entering the resistor from an inside of the SOI substrate.

According to a fifth aspect of the present invention, a semiconductor device includes a resistor formed by a silicon film, an interlayer insulating film covering the resistor, a contact plug formed by a different material from a material of the interlayer insulating film and connected to the resistor, a wiring formed by a different material from the material of the interlayer insulating film and connected to the contact plug, and a dummy contact plug formed by a different material from the material of the interlayer insulating film and connected to the wiring in a position in which the resistor is not covered in the vicinity thereof. The different material has the function of preventing a hydrogen atom from entering the resistor.

The dummy contact plug connected to the wiring provided above the resistor is formed by the different material from the material of the interlayer insulating film in the position in which the resistor is not covered in the vicinity thereof. Since the different material has the function of preventing a hydrogen atom from entering the resistor, it is possible to more reliably prevent the hydrogen atom from entering the resistor in a direction in which the wiring is extended. Thus, it is possible to obtain a semiconductor device in which a resistance value of the resistor formed by the silicon film is changed with difficulty.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a semiconductor device according to a first embodiment,

FIG. 2 is a sectional view showing a variant of the semiconductor device according to the first embodiment,

FIGS. 3 to 8 are views showing a method of manufacturing the semiconductor device according to the first embodiment,

FIG. 9 is a sectional view showing a semiconductor device according to a second embodiment,

FIGS. 10 to 15 are views showing a method of manufacturing the semiconductor device according to the second embodiment,

FIG. 16 is a sectional view showing a semiconductor device according to a third embodiment,

FIG. 17 is a top view showing a semiconductor device according to a fourth embodiment,

FIG. 18 is a sectional view showing the semiconductor device according to the fourth embodiment,

FIG. 19 is another sectional view showing the semiconductor device according to the fourth embodiment,

FIGS. 20 to 25 are views showing a method of manufacturing the semiconductor device according to the fourth embodiment,

FIG. 26 is a top view showing a semiconductor device according to a fifth embodiment,

FIG. 27 is a sectional view showing the semiconductor device according to the fifth embodiment,

FIG. 28 is another sectional view showing the semiconductor device according to the fifth embodiment,

FIG. 29 is a sectional view showing a semiconductor device according to a sixth embodiment,

FIG. 30 is a top view showing a semiconductor device according to a seventh embodiment,

FIG. 31 is a sectional view showing the semiconductor device according to the seventh embodiment,

FIG. 32 is a top view showing a semiconductor device according to an eighth embodiment,

FIG. 33 is a sectional view showing the semiconductor device according to the eighth embodiment,

FIG. 34 is a view showing problems of the semiconductor device according to the seventh embodiment,

FIG. 35 is a top view showing a semiconductor device according to a ninth embodiment,

FIG. 36 is a sectional view showing the semiconductor device according to the ninth embodiment,

FIG. 37 is a sectional view showing a variant of the semiconductor device according to the ninth embodiment,

FIG. 38 is a top view showing a conventional semiconductor device, and

FIG. 39 is a sectional view showing the conventional semiconductor device.

### DESCRIPTION OF THE PREFERRED EMBODIMENTS

### First Embodiment

The present embodiment provides a semiconductor device in which a resistor is formed by an amorphous silicon film and a silicide is formed in connecting portions of contact plugs in a surface portion thereof.

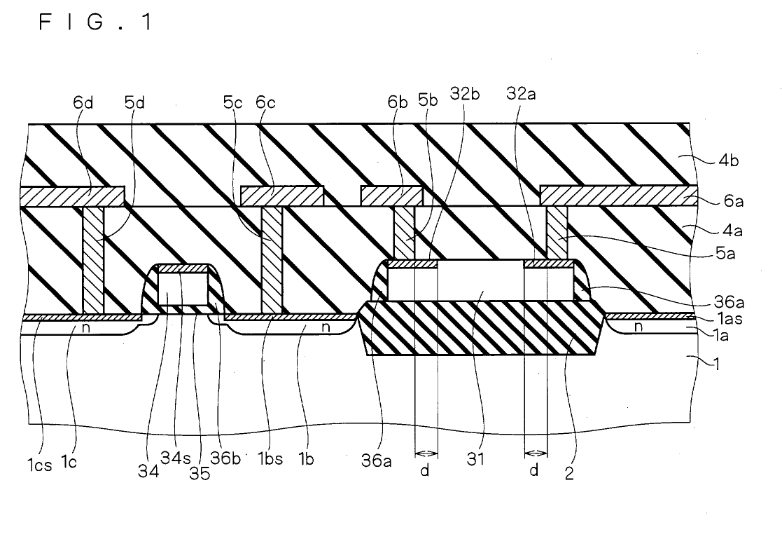

FIG. 1 is a view showing the semiconductor device according to the present embodiment. As shown in FIG. 1, in the semiconductor device, a resistor 31 is formed by an amorphous silicon film and is provided on an isolating region 2 in a semiconductor substrate 1. A sidewall insulating film 36a is formed on a side surface of the resistor 31, and contact plugs 5a and 5b are connected to both ends of a surface thereof. Silicides 32a and 32b are formed in connecting portions of the contact plugs 5a and 5b in the surface portion of the resistor 31. The contact plugs 5a and 5b are connected to wirings 6a and 6b provided on a first interlayer insulating film 4a, respectively. A second interlayer insulating film 4b is formed on the wirings 6a and 6b.

The semiconductor substrate 1 is a silicon substrate, for example, and the isolating region 2 is formed by a silicon oxide film, for example. Active regions 1a to 1c having an impurity ion implanted at a high concentration are formed on a surface of the semiconductor substrate 1.

Moreover, FIG. 1 also shows a MOS transistor formed on the semiconductor substrate 1. The MOS transistor comprises the active regions 1b and 1c as a source and a drain, and furthermore, a gate insulating film 35, a gate electrode 34 and a sidewall insulating film 36b. Silicides 1as, 1bs, 1cs and 34s are formed on the active regions 1a, 1b and 1c and a surface of the gate electrode 34, respectively. Contact plugs 5c and 5d are linked to the suicides 1bs and 1cs, respectively. The contact plugs 5c and 5d are connected to wirings 6c and 6d provided on the first interlayer insulating film 4a, respectively.

The contact plugs 5a to 5d are formed by tungsten plugs, for example, and the wirings 6a to 6d are formed by aluminum wirings, for example. The first and second interlayer insulating films 4a and 4b are formed by a silicon oxide film, for example. Moreover, the gate electrode 34 is formed by a polycrystalline silicon film, for example.

According to the semiconductor device of the present embodiment, the resistor 31 is amorphous silicon. Therefore, it is possible to obtain a semiconductor device in which a hydrogen atom is introduced with more difficulty and a resistance value of the resistor formed by a silicon film is changed with more difficulty as compared with the case in which polycrystalline silicon is used for a material of the resistor.

Moreover, the silicides 32a and 32b are formed in the connecting portions of the contact plugs 5a and 5b in the surface portion of the resistor 31. When contact holes for the contact plugs 5a and 5b are to be formed in the first interlayer insulating film 4a by etching, accordingly, the resistor 31 is etched with difficulty.

When the surface of the resistor 31 is etched, a value of a contact resistance of the connecting portions of the contact plugs 5a and 5b is varied easily. If the silicides 32a and 32b are formed, however, a variation in the value of the contact resistance is generated with difficulty. Consequently, it is possible to obtain a semiconductor device in which the resistance value of the resistor 31 is changed with more difficulty. It is preferable that margins d from ends of the contact plugs 5a and 5b to those of the silicides 32a and 32b should be set to be approximately 1 μm.

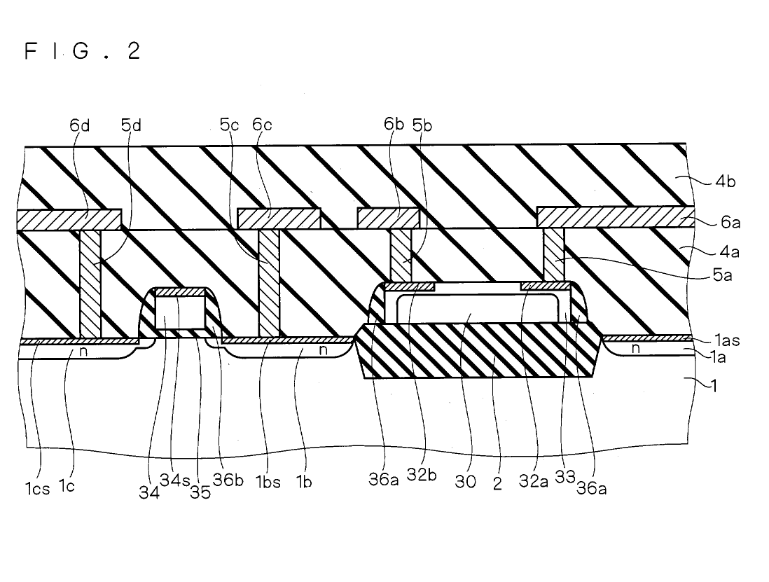

Moreover, FIG. 2 shows a variant of the semiconductor device according to the present embodiment. As shown in FIG. 2, it is also possible to employ a structure in which a surface portion of a resistor 30 formed by a polycrystalline silicon film is provided as an amorphous silicon layer 33 in place of the resistor 31 formed by the amorphous silicon film in FIG. 1. If at least the surface portion of the resistor 30 is provided as the amorphous silicon layer 33, the function of preventing a hydrogen atom from entering the resistor can be obtained.

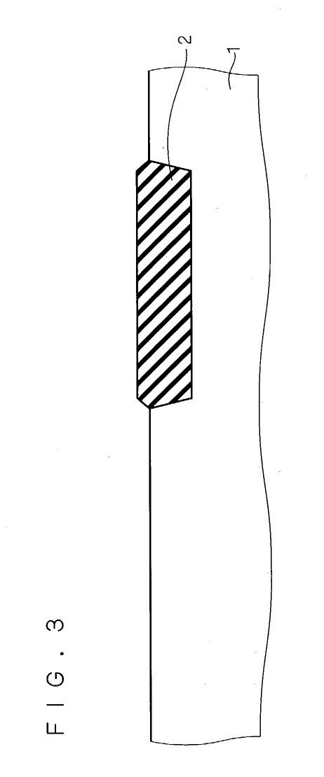

FIGS. 3 to 8 are views showing a method of manufacturing the semiconductor device according to the present embodiment.

As shown in FIG. 3, first of all, the isolating region 2 is formed in the semiconductor substrate 1 by thermal oxidation or the like. Then, an impurity ion such as boron is implanted in a channel region of the MOS transistor at an energy of several tens to several hundreds keV. It is preferable that an ion implantation concentration should be in order of 10¹² cm⁻². By the thermal oxidation or the like, subsequently, an insulating film is formed in a portion on the channel region.

Next, a polycrystalline silicon film is formed over a whole surface and a nitrogen ion is implanted therein at an energy of approximately several tens keV. It is preferable that an ion implantation concentration should be in order of 10¹⁵ cm⁻². Moreover, a phosphorus ion is implanted in the polycrystalline silicon film at an energy of approximately several tens keV. It is preferable that an ion implantation concentration should be in order of 10¹⁵ cm⁻².

Then, the resistor 30, the gate insulating film 35 and the gate electrode 34 are formed by using photolithography and etching as shown in FIG. 4. It is preferable that the gate insulating film 35 should have a thickness of approximately several nm and the gate electrode 34 should have a thickness of approximately several hundreds nm.

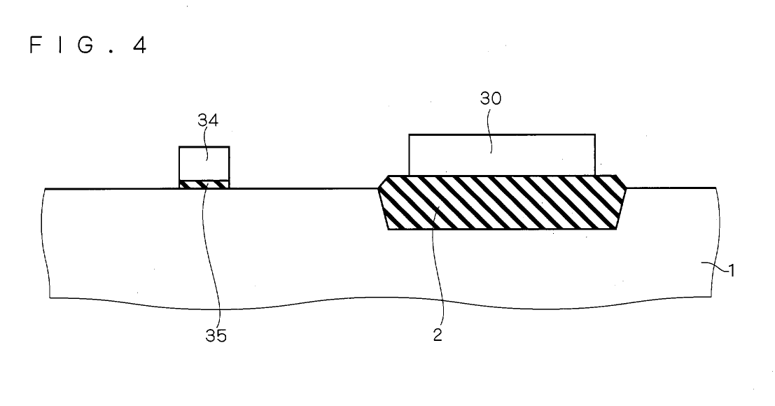

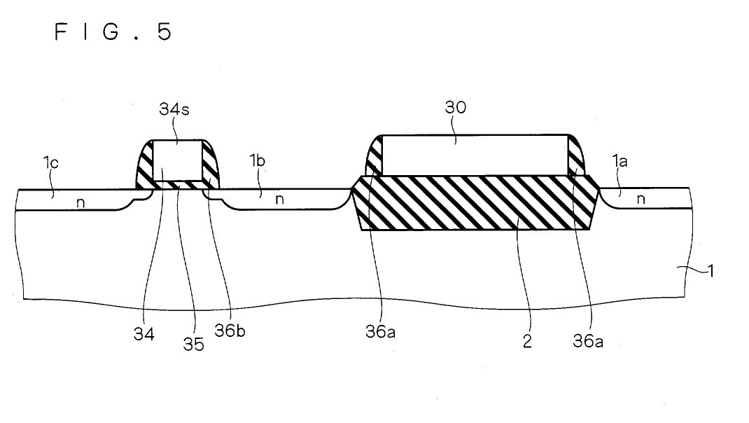

Next, an impurity ion such as arsenic is implanted in the semiconductor substrate 1 at an energy of approximately several tens keV. Subsequently, an insulating film such as a silicon oxide film is formed over the whole surface by a CVD (Chemical Vapor Deposition) method or the like, for example, and etch back is carried out to form the sidewall insulating films 36a and 36b as shown in FIG. 5. Then, the impurity ion such as arsenic is implanted in the semiconductor substrate 1 at an energy of approximately several tens keV again so that the active regions 1a to 1c are formed. It is preferable that an ion implantation concentration in the active regions 1a to 1c should be in order of 10¹⁵ cm⁻².

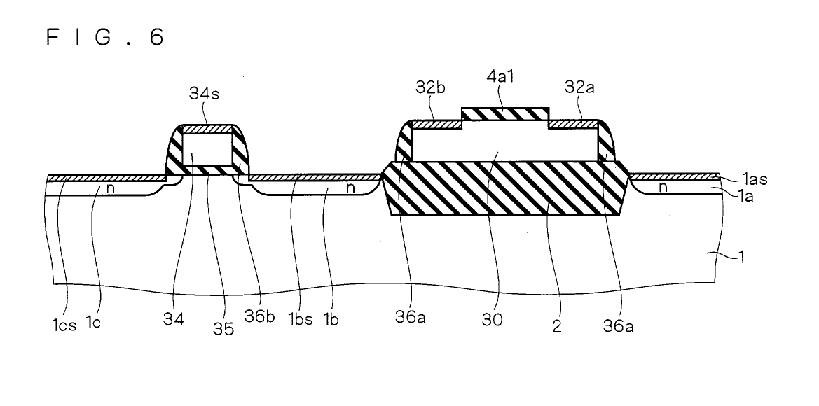

Thereafter, an insulating film (for example, a silicon oxide film) 4a1 for preventing formation of a silicide is provided on the resistor 30. Next, each of the surfaces of the semiconductor substrate 1, the gate electrode 34, the active regions 1a to 1c and a part of the resistor 30 which is not covered with the insulating film 4a1 is silicided to form the silicides 1as to 1cs, 32a, 32b and 34s as shown in FIG. 6. In FIGS. 1 and 2, the insulating layer 4a1 is not shown.

As shown in FIG. 7, subsequently, a portion other than the resistor 30 is covered with a photoresist PR1 and a silicon ion implantation IP1 is carried out at an energy of approximately several tens keV. It has been known that a polycrystalline silicon film becomes amorphous if the silicon ion is implanted in the resistor 30 formed by the polycrystalline silicon film. In order to manufacture the structure of FIG. 2, accordingly, it is preferable that an energy amount in the silicon implantation should be decreased in the manufacture of the structure in FIG. 1. Preferably, an ion implantation concentration is in order of 10¹⁵ cm⁻².

In FIG. 7, the gate electrode 34 is covered with the photoresist PR1 and is thereby maintained to be polycrystalline silicon. However, the gate electrode 34 may be amorphous. Moreover, a change to an amorphous state may be carried out in any of stages in FIGS. 4 to 6.

As shown in FIG. 8, then, the photoresist PR1 is removed and the first interlayer insulating film 4a is formed. Thereafter, a contact hole is formed in each portion of the first interlayer insulating film 4a and a conductive film such as tungsten is formed therein. Subsequently, a CMP (Chemical Mechanical Polishing) treatment is carried out over a surface to form the contact plugs 5a to 5d. Then, a conductive film such as aluminum is formed and is subjected to patterning so that the wirings 6a to 6d are formed.

Thereafter, the second interlayer insulating film 4b is formed. Thus, the structure shown in FIG. 1 or 2 can be manufactured.

### Second Embodiment

The present embodiment provides a semiconductor device in which a resistor is formed by a silicon film, a surface thereof is covered with a silicon nitride film and a silicide is formed in connecting portions of contact plugs in a surface portion thereof.

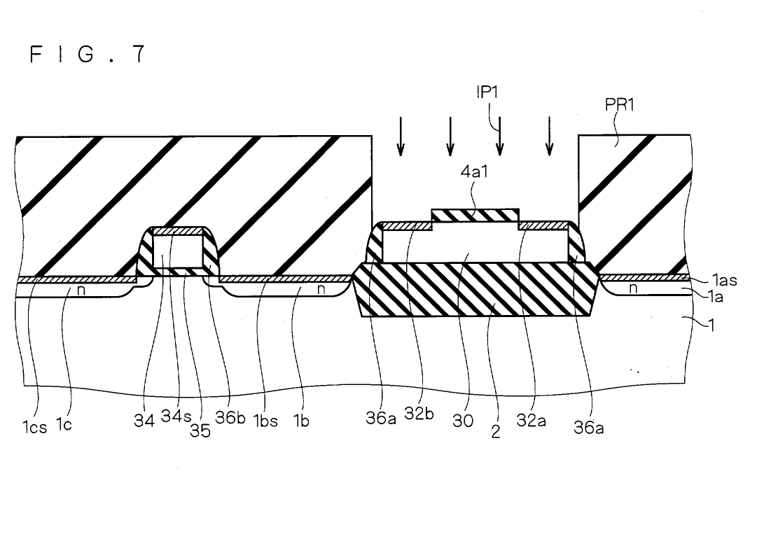

FIG. 9 is a view showing a semiconductor device according to the present embodiment. As shown in FIG. 9, in the semiconductor device, a resistor 30 is formed by a polycrystalline silicon film and is provided on an isolating region 2 through an underlaid silicon nitride film 41. Moreover, a silicon nitride film 42 is formed to cover an upper surface and a side surface of the resistor 30.

Since other structures are the same as those of the semiconductor device according to the first embodiment, description will be omitted.

The silicon nitride film has the function of preventing a hydrogen atom from entering the resistor 30. According to the semiconductor device of the present embodiment, therefore, the underlaid silicon nitride film 41 and the silicon nitride film 42 cover the surface of the resistor 30 so that a resistance value of the resistor 30 formed by the silicon film is changed with difficulty. Moreover, silicides 32a and 32b are formed in connecting portions of contact plugs 5a and 5b in the surface portion of the resistor 30. Accordingly, it is possible to obtain a semiconductor device in which the resistor 30 is etched with difficulty at time of etching for forming a contact hole and the resistance value of the resistor 30 is changed with more difficulty.

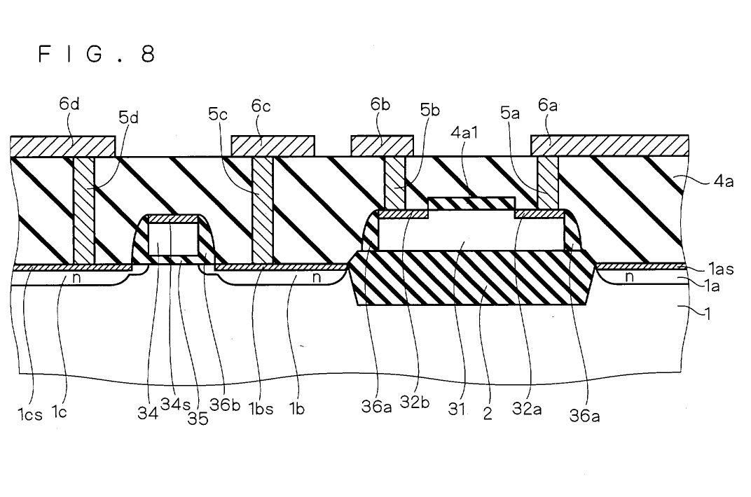

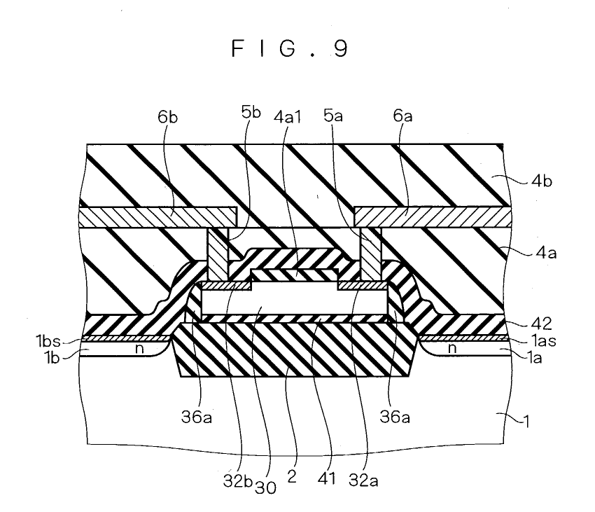

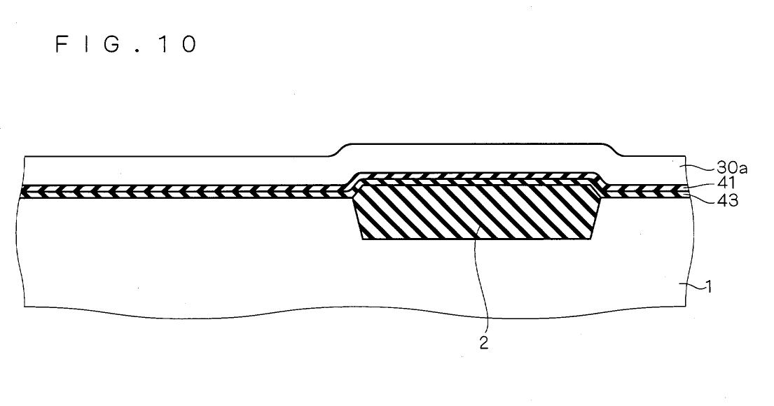

FIGS. 10 to 15 are views showing a method of manufacturing the semiconductor device according to the present embodiment.

As shown in FIG. 10, first of all, an isolating region 2 is formed in a semiconductor substrate 1. Then, a silicon oxide film 43, a silicon nitride film 41 and a polycrystalline silicon film 30a are provided on the semiconductor substrate 1 in this order. Respective thicknesses are approximately several tens nm, several tens nm and several hundreds nm, for example.

As shown in FIG. 11, thereafter, a photoresist PR2 is formed and is used as an etching mask to carry out etching. Thus, the resistor 30 is formed. At this time, the silicon oxide film 43 and the silicon nitride film 41 are also etched. Subsequently, the photoresist PR2 is removed.

Then, an impurity ion such as boron is implanted in a channel region of an MOS transistor at an energy of several tens to several hundreds keV. It is preferable that an ion implantation concentration should be in order of 10¹² cm⁻². Thereafter, an insulating film is formed in a portion on the channel region by thermal oxidation or the like.

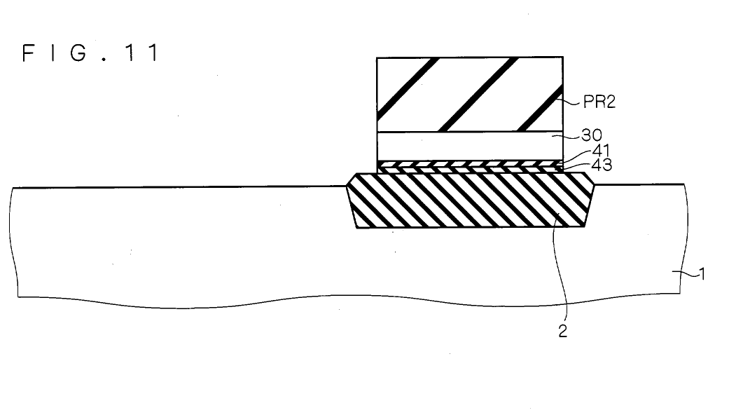

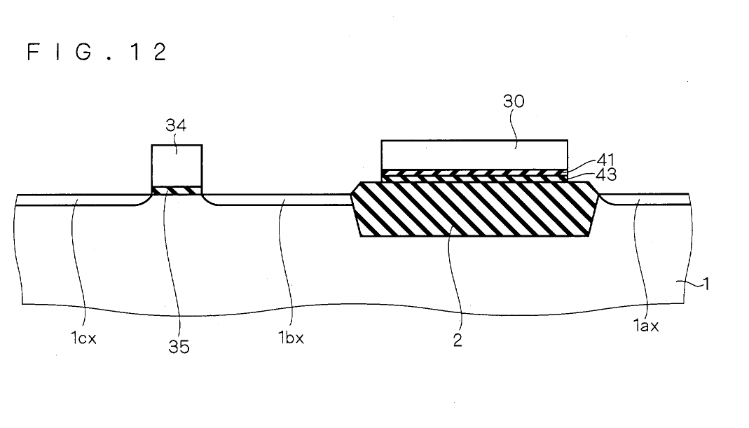

Next, a polycrystalline silicon film is formed over a whole surface and the insulating film and the polycrystalline silicon film are subjected to patterning to form a gate insulating film 35 and a gate electrode 34 (FIG. 12). It is preferable that the gate insulating film 35 should have a thickness of approximately several tens nm and the gate electrode 34 should have a thickness of approximately several hundreds nm.

Then, an arsenic ion is implanted in the semiconductor substrate 1 at an energy of approximately several tens keV, for example. Thus, extension regions 1ax to 1cx in active regions 1a to 1c are formed. It is also preferable that an ion implantation concentration should be in order of 10¹⁵ cm⁻².

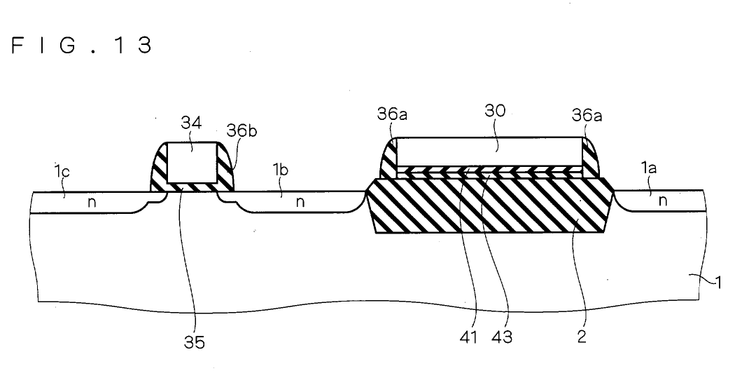

Thereafter, an insulating film is formed over a whole surface and etch back is carried out to form sidewall insulating films 36a and 36b (FIG. 13). Subsequently, an arsenic ion is implanted in the semiconductor substrate 1 at an energy of approximately several tens keV, for example. Thus, the active regions 1a to 1c are formed. It is preferable that an ion implantation concentration should be in order of 10¹⁵ cm⁻².

As shown in FIG. 14, next, an insulating film (for example, a silicon oxide film) 4a1 for preventing formation of a silicide is provided on the resistor 30. Then, each surface of the semiconductor substrate 1, the gate electrode 34, the active regions 1a to 1c and a part of the resistor 30 which is not covered with the insulating film 4a1 is silicided to form silicides 1as to 1cs, 32a, 32b and 34s. Thereafter, the silicon nitride film 42 is formed over the whole surface.

As shown in FIG. 15, subsequently, a first interlayer insulating film 4a is formed. Then, a contact hole is formed in each portion of the first interlayer insulating film 4a and the silicon nitride film 42 and a conductive film such as tungsten is formed therein. Thereafter, a CMP treatment is carried out over a surface to form contact plugs 5a to 5d. Subsequently, a conductive film such as aluminum is formed and is subjected to patterning to form wirings 6a to 6d.

Then, a first interlayer insulating film 4b is formed. Thus, the structure shown in FIG. 9 can be manufactured. Although the silicon oxide film 43 is not shown in FIG. 9, the formation of the silicon oxide film 43 is optional. In FIG. 9, if only the silicon nitride film 41 is formed under the resistor 30, a stress is applied to surfaces of the semiconductor substrate 1 and the isolating region 2 in some cases. Accordingly, FIGS. 10 to 15 simply show the case in which the silicon oxide film is provided as an underlaid layer of the silicon nitride film in order to relieve the stress.

In the present embodiment, it is also possible to employ the resistor 31 formed by an amorphous silicon film in FIG. 1 and a combination of the resistor 30 formed by a polycrystalline silicon film and the amorphous silicon layer 33 in FIG. 2 in place of the resistor 30 formed by a polycrystalline silicon film.

### Third Embodiment

The present embodiment provides a semiconductor device in which a resistor is formed by a silicon film and a lower surface thereof is covered with a silicon germanium film.

FIG. 16 is a view showing a semiconductor device according to the present embodiment. As shown in FIG. 16, in the semiconductor device, a resistor 30 is formed by a polycrystalline silicon film and is provided on an isolating region 2 through a silicon germanium film 44.

Since other structures are the same as those of the semiconductor device according to the first embodiment, description will be omitted. Also in FIG. 16, a sidewall insulating film 36a is not formed.

The silicon germanium film has the function of activating an impurity in the resistor 30. According to the semiconductor device of the present embodiment, therefore, the silicon germanium film 44 is provided in contact with a lower surface of the resistor 30. Therefore, it is possible to reduce a resistance value of the resistor 30 formed by a silicon film. Accordingly, it is possible to obtain a semiconductor device in which the resistance value of the resistor 30 is changed with difficulty.

### Fourth Embodiment

The present embodiment provides a semiconductor device in which a resistor is formed by a silicon film and a region of a surface of the resistor which is interposed between wirings and contact plugs is covered with a dummy contact plug insulated from the resistor.

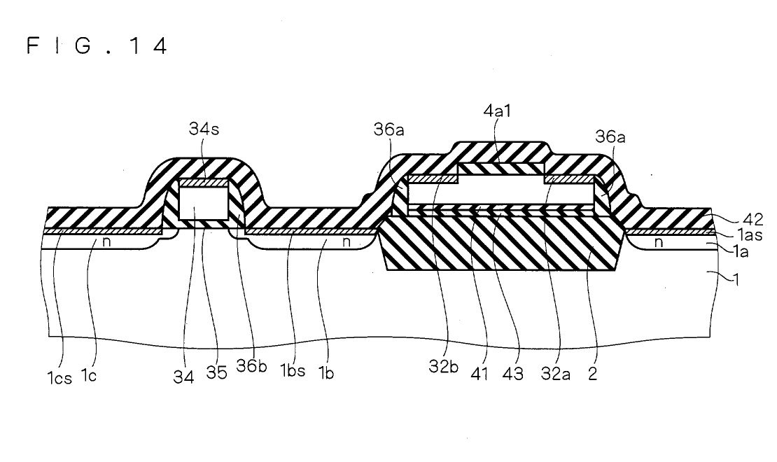

FIG. 17 is a top view showing the semiconductor device according to the present embodiment. Moreover, FIGS. 18 and 19 are sectional views taken along cutting lines XVIII-XVIII and XIX-XIX in FIG. 17, respectively.

As shown in FIGS. 17 to 19, in the semiconductor device, a resistor 30 is formed by a polycrystalline silicon film and is provided on an isolating region 2. Moreover, a silicon oxide film 45 and a silicon nitride film 46 are formed to cover an upper surface and a side surface of the resistor 30. A dummy contact plug 5e insulated from the resistor 30 through the silicon oxide film 45 and the silicon nitride film 46 and a dummy wiring 6e formed on the dummy contact plug 5e are further provided on the silicon nitride film 46. It is preferable that the dummy contact plug 5e should be formed by a tungsten plug, for example, in the same manner as the contact plugs 5a and 5b, and the dummy wiring 6e should be formed by an aluminum wiring, for example, in the same manner as the wirings 6a and 6b.

Since other structures are the same as those of the semiconductor device according to the second embodiment shown in FIG. 9, description will be omitted. In FIGS. 18 and 19, a sidewall insulating film 36a is formed.

According to the semiconductor device of the present embodiment, a region in a surface portion of the resistor 30 which is interposed between the wirings 6a and 6b and the contact plugs 5a and 5b is covered with the dummy contact plug 5e and the dummy wiring 6e which are formed by a different material from a material of first and second interlayer insulating films 4a and 4b covering the resistor 30, and which are insulated from the resistor 30. Accordingly, the dummy contact plug 5e and the dummy wiring 6e are formed by a different material from the material of the first and second interlayer insulating films 4a and 4b. Thus, a hydrogen atom can be prevented from entering the resistor 30. In particular, if the dummy contact plug 5e and/or the dummy wiring 6e are/is formed of metal such as tungsten or aluminum, the preventing function can be more enhanced. Moreover, the dummy contact plug 5e and/or the dummy wiring 6e can easily be formed of metal. Thus, it is possible to obtain a semiconductor device in which a resistance value of the resistor 30 formed by a silicon film is changed with difficulty.

Moreover, the dummy contact plug 5e and the dummy wiring 6e are insulated from the resistor 30. Therefore, the resistance value of the resistor 30 formed by the silicon film is not influenced and is changed with more difficulty.

The silicon nitride film 46 according to the present embodiment serves to prevent the hydrogen atom from entering the resistor 30 in the same manner as the silicon nitride film 42 according to the second embodiment. Furthermore, the silicon oxide film 45 provided under the silicon nitride film 46 also serves to relieve a stress to be applied to a transistor (not shown) in the same manner as the silicon oxide film 43 shown in FIG. 11.

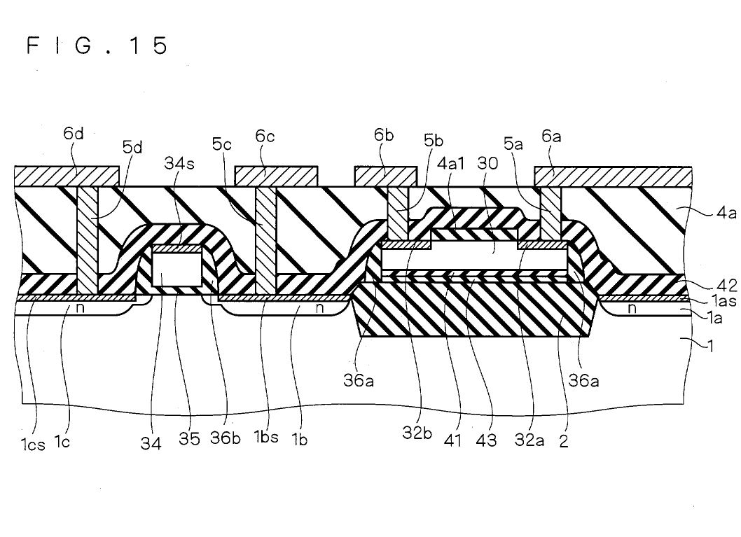

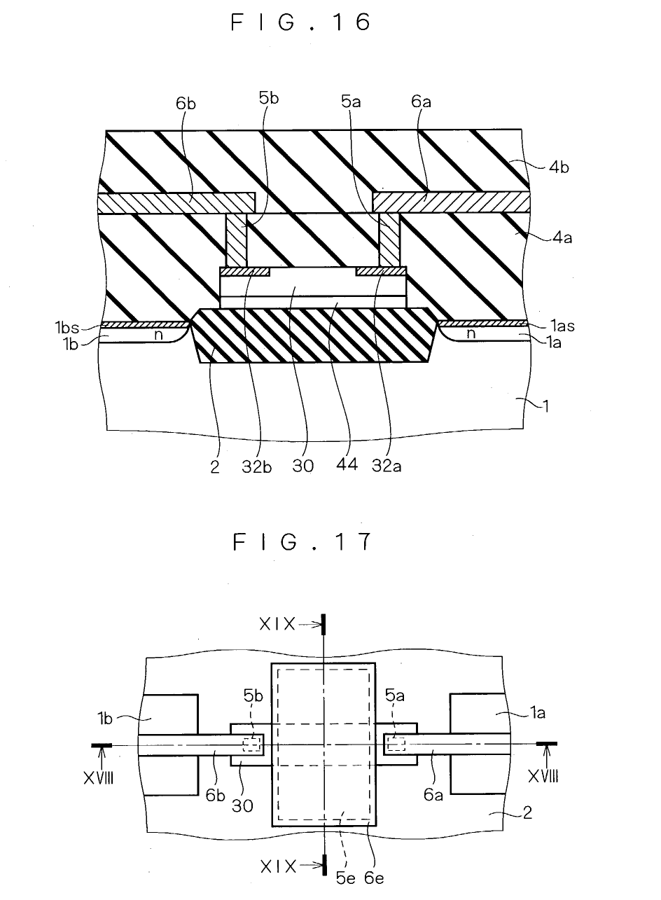

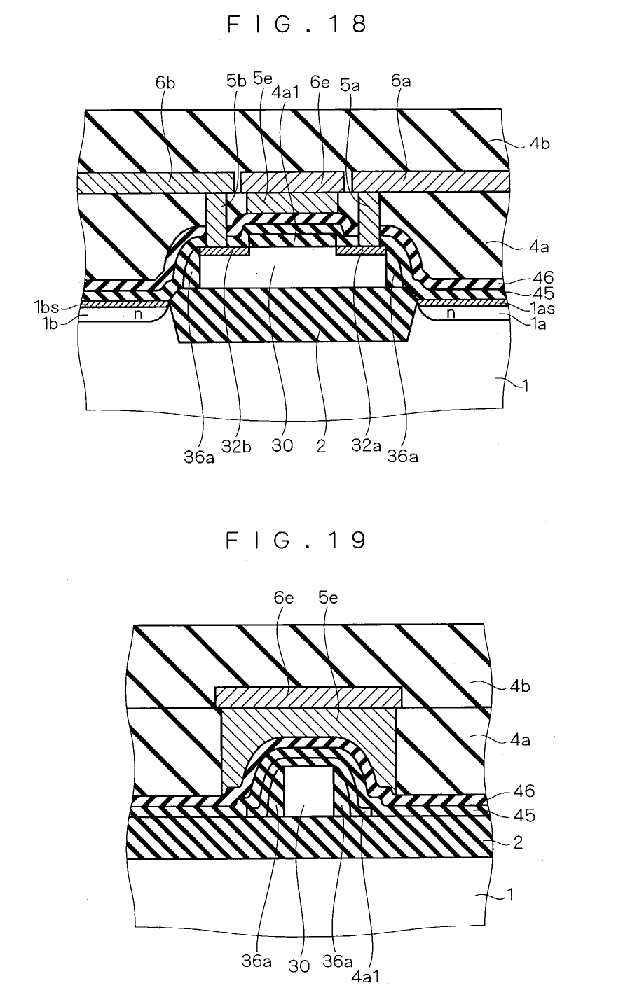

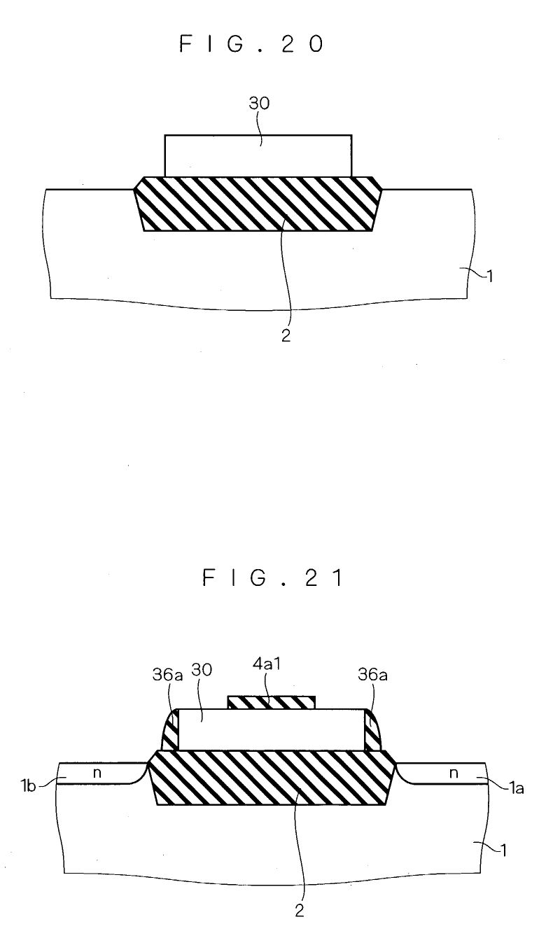

FIGS. 20 to 25 are views showing a method of manufacturing the semiconductor device according to the present embodiment.

As shown in FIG. 20, first of all, the isolating region 2 is formed in a semiconductor substrate 1. Then, an ion is implanted into a channel region of an adjacent MOS transistor (not shown). Thereafter, an insulating film is formed on a portion of a channel region by thermal oxidation or the like.

Next, a polycrystalline silicon film is formed over a whole surface and the insulating film and the polycrystalline silicon film are subjected to patterning to form a gate insulating film and a gate electrode of the MOS transistor which is not shown, and the resistor 30. It is preferable that an ion should be implanted into the polycrystalline silicon film at an energy of approximately several tens to several hundreds keV, for example. It is preferable that an ion implantation concentration should be in order of 10¹⁵ cm⁻², for example.

Subsequently, a silicon oxide film or the like is formed over the whole surface and etch back is carried out to form a sidewall insulating film 36a around the resistor 30 as shown in FIG. 21. Then, an ion is implanted into the semiconductor substrate 1 to form active regions 1a and 1b. Moreover, an insulating film (for example, a silicon oxide film) 4a1 for preventing formation of a silicide is provided on the resistor 30.

As shown in FIG. 22, thereafter, each surface of the semiconductor substrate 1, a gate electrode of the MOS transistor which is not shown, the active regions 1a and 1b and a part of the resistor 30 which is not covered with the insulating film 4a1 is silicided to form silicides 1as, 1bs, 32a and 32b. Subsequently, the silicon oxide film 45 and the silicon nitride film 46 are formed over the whole surface and the first interlayer insulating film 4a is formed.

As shown in FIG. 23, next, a photoresist PR3 is formed on the first interlayer insulating film 4a and is subjected to patterning for forming the dummy contact plug 5e. Then, etching is carried out to form a contact hole OP1 in the first interlayer insulating film 4a.

As shown in FIG. 24, subsequently, a photoresist PR4 is formed over the whole surface and is subjected to patterning for forming the contact plugs 5a and 5b. Then, the etching is carried out to form a contact hole OP2 in the first interlayer insulating film 4a, the silicon nitride film 46 and the silicon oxide film 45.

As shown in FIG. 25, thereafter, a conductive film such as tungsten is formed in the contact holes OP1 and OP2 to carry out a CMP treatment over a surface. Thus, the contact plugs 5a and 5b and the dummy contact plug 5e are formed. Subsequently, a conductive film such as aluminum is formed and is subjected to patterning so that the wirings 6a and 6b and the dummy wiring 6e are formed.

Then, a second interlayer insulating film 4b is formed. Thus, the structure shown in FIGS. 17 to 19 can be manufactured.

In the present embodiment, it is also possible to employ the resistor 31 formed by an amorphous silicon film shown in FIG. 1 and a combination of the resistor 30 formed by a polycrystalline silicon film and the amorphous silicon layer 33 in FIG. 2 in place of the resistor 30 formed by a polycrystalline silicon film.

For materials of the contact plugs 5a and 5b, the dummy contact plug 5e, the wirings 6a and 6b and the dummy wiring 6e, moreover, it is also possible to employ copper, titanium, nickel, cobalt or the like in place of tungsten and aluminum, for example.

### Fifth Embodiment

The present embodiment is a variant of the semiconductor device according to the fourth embodiment, in which a part of the first interlayer insulating film 4a is buried in the dummy contact plug 5e shown in FIGS. 17 to 19.

In the case of the dummy contact plug 5e, as shown in FIG. 23, an opening of a contact hole OP1 is large. If the opening is large, a conductive film is not perfectly buried and a burying insufficiency is caused in some cases. When the burying insufficiency is caused, there is a possibility that a foreign substance generated during the CMP treatment might enter a burying insufficient portion to influence an element characteristic. In the present embodiment, the semiconductor device has such a structure that the burying insufficiency is caused with difficulty.

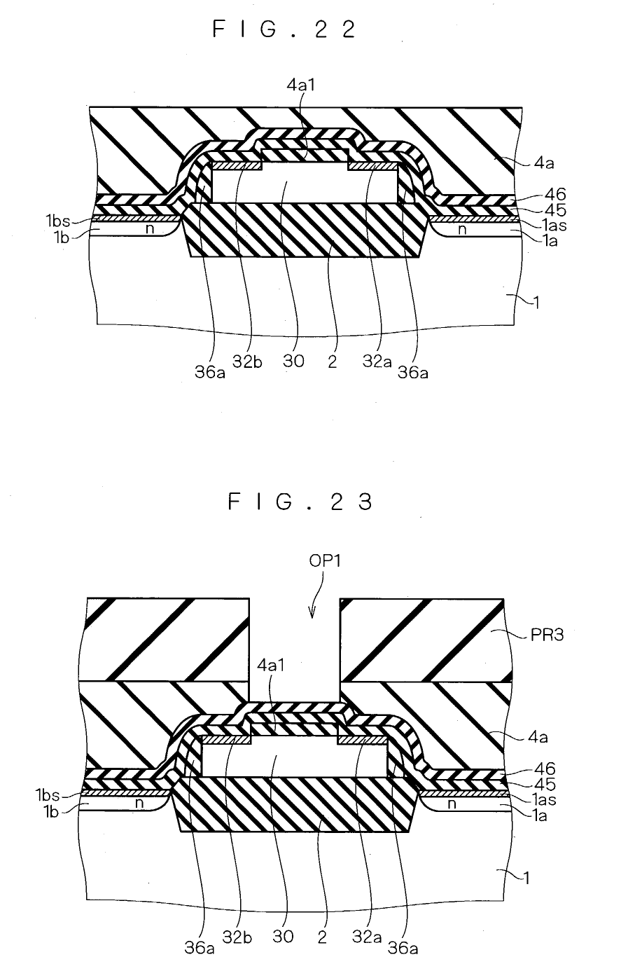

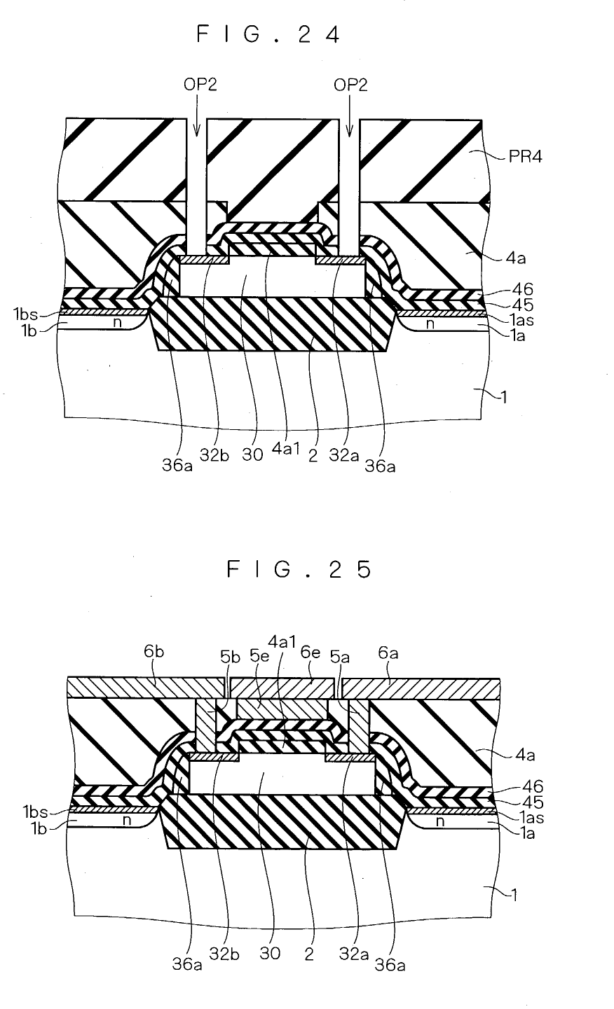

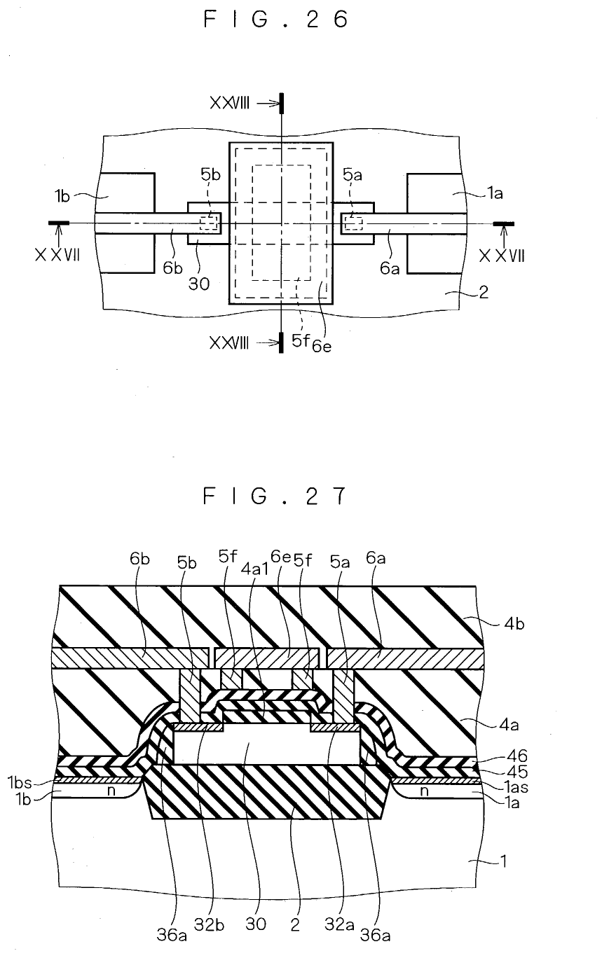

FIG. 26 is a top view showing the semiconductor device according to the present embodiment. Moreover, FIGS. 27 and 28 are sectional views taken along cutting lines XXVII-XXVII and XXVIII-XXVIII in FIG. 26, respectively.

As shown in FIGS. 26 to 28, in the semiconductor device, a dummy contact plug 5f having a hollow shape is formed in place of the dummy contact plug 5e having a large opening of the contact hole shown in FIGS. 17 to 19. It is preferable that the dummy contact plug 5f should also be formed by a tungsten plug, for example, in the same manner as the contact plugs 5a and 5b. Moreover, a part of the first interlayer insulating film 4a is buried in a hollow portion of the dummy contact plug 5f.

Since other structures are the same as those of the semiconductor device according to the fourth embodiment shown in FIGS. 17 to 19, description will be omitted.

According to the semiconductor device of the present embodiment, a part of the first interlayer insulating film 4a is buried in the dummy contact plug 5f. Consequently, it is preferable that a conductive film should be buried in only a portion surrounding a part of the first interlayer insulating film 4a which is buried. Therefore, the burying insufficiency is caused with difficulty during formation of the dummy contact plug 5f. Accordingly, it is possible to reduce a possibility that a foreign substance might enter the dummy contact plug 5f.

### Sixth Embodiment

The present embodiment is also a variant of the semiconductor device according to the fourth embodiment, and the dummy contact plug 5e and the dummy wiring 6e in FIGS. 17 to 19 are multilayered.

FIG. 29 is a sectional view showing a semiconductor device according to the present embodiment. As shown in FIG. 29, in the semiconductor device, a dummy contact plug 5g is further provided on the dummy wiring 6e in a second interlayer insulating film 4b. A dummy wiring 6f is further provided on the dummy contact plug 5g and the second interlayer insulating film 4b. Wirings 6g and 6h are also formed on the second interlayer insulating film 4b.

Since other structures are the same as those of the semiconductor device according to the fourth embodiment shown in FIGS. 17 to 19, description will be omitted.

According to the semiconductor device of the present embodiment, the dummy contact plug 5g is further formed on the dummy wiring 6e. Therefore, it is possible to obtain a semiconductor device in which a hydrogen atom can be more prevented from entering a resistor 30 and a resistance value of the resistor 30 formed by a silicon film is changed with more difficulty.

### Seventh Embodiment

The present embodiment provides a semiconductor device in which a dummy contact plug is provided in the vicinity of a resistor formed by a silicon film on an SOI (Silicon On Insulator) substrate.

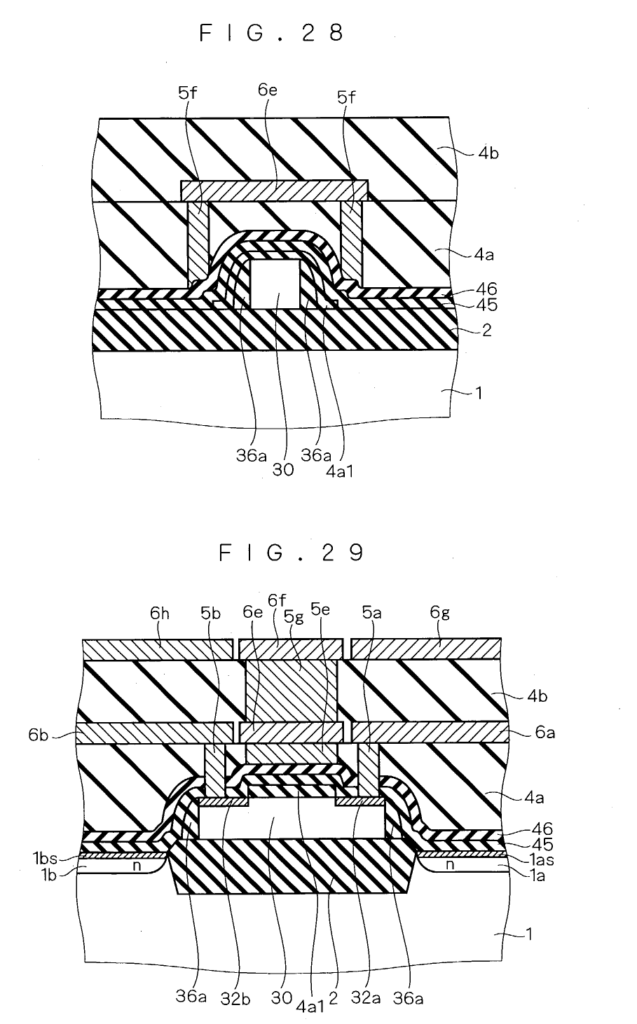

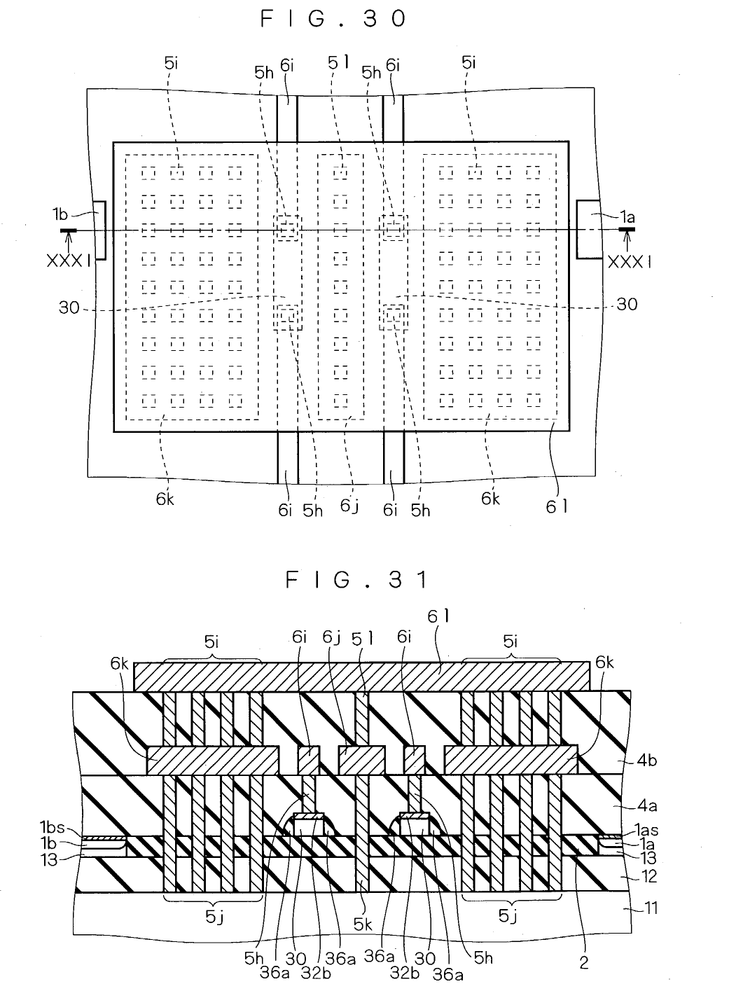

FIGS. 30 and 31 are a top view and a sectional view which show the semiconductor device according to the present embodiment, respectively. FIG. 31 is a sectional view taken along a cutting line XXXI-XXXI in FIG. 30.

As shown in FIGS. 30 and 31, in the semiconductor device, a semiconductor substrate is an SOI substrate including a laminating structure having a support substrate 11 such as a silicon substrate, a buried insulating film 12 such as a silicon oxide film and a silicon layer 13.

A resistor 30 is formed by a polycrystalline silicon film and is provided on an isolating region 2 in the silicon layer 13. A sidewall insulating film 36a is formed on a side surface of the resistor 30, and a contact plug 5h to be a tungsten plug is connected to both ends of a surface, for example. A silicide 32b is formed in a connecting portion of the contact plug 5h in a surface portion of the resistor 30. Each contact plug 5h is connected to a wiring 6i to be an aluminum wiring provided on a first interlayer insulating film 4a, for example. A second interlayer insulating film 4b is formed on the first interlayer insulting film 4a and the wiring 6i.

The isolating region 2 is formed by a silicon oxide film, for example. Moreover, active regions 1a and 1b having an impurity ion implanted at a high concentration are formed on a surface of the SOI layer 13. Silicides 1as and 1bs are also formed on surfaces of the active regions 1a and 1b, respectively.

In the present embodiment, dummy contact plugs 5j and 5k penetrating through the first interlayer insulating film 4a, the buried insulating film 12 and the isolating region 2 formed in the silicon layer 13 are provided in the vicinity of the resistor 30. Moreover, dummy wirings 6k and 6j to be connected to the dummy contact plugs 5j and 5k respectively are also formed on the first interlayer insulating film 4a.

Other dummy contact plugs 5i and 5l to be connected to the dummy wirings 6k and 6j respectively are also formed in the second interlayer insulating film 4b. A dummy wiring 6l covering a portion above the resistor 30 and connected to the dummy contact plugs 5i and 5l in common is also formed on the second interlayer insulating film 4b.

It is preferable that the dummy contact plugs 5i to 5l should be formed by tungsten plugs, for example, in the same manner as the contact plug 5h and the dummy wirings 6j to 6l should be formed by an aluminum wiring, for example, in the same manner as the wiring 6i. Moreover, the dummy contact plugs 5i to 5l comprise a plurality of columnar conductors and are juxtaposed.

According to the semiconductor device of the present embodiment, the dummy contact plugs 5i to 5l and the dummy wirings 6j to 6l are formed by a different material from a material of the first and second interlayer insulating films 4a and 4b (a material such as metal having the function of preventing a hydrogen atom from entering the resistor 30) in the vicinity of the resistor 30. Accordingly, it is possible to obtain a semiconductor device in which the dummy contact plugs 5i to 5l and the dummy wirings 6j to 6l prevent the hydrogen atom from entering the resistor 30 and a resistance value of the resistor 30 formed by a silicon film is changed with difficulty.

If the dummy contact plugs 5i to 5l and the dummy wirings 6j to 6l are formed of metal, the function of preventing the hydrogen atom from entering the resistor 30 can be more enhanced. Moreover, since the metal is used for the material, the dummy contact plugs 5i to 5l and the dummy wirings 6j to 6l can be formed easily.

Moreover, the dummy contact plug 5j penetrates through the buried insulating film 12 of the SOI substrate and the silicon layer 13. Consequently, it is possible to more reliably prevent the hydrogen atom from entering the resistor 30 from an inside of the SOI substrate.

Furthermore, the dummy wiring 6l covering the portion above the resistor 30 is formed. Therefore, it is possible to obtain a semiconductor device in which the hydrogen atom can be more reliably prevented from entering the resistor 30 from above and the resistance value of the resistor 30 formed by a silicon film is changed with difficulty.

Moreover, the dummy contact plugs 5i to 5l comprise a plurality of columnar conductors and are juxtaposed. If it is assumed that each of the dummy contact plugs is not divided into a plurality of columnar conductors but is integrated in FIG. 30, it is necessary to bury a conductive film in a large opening. In this case, the conductive film is not buried perfectly and a burying insufficiency might be caused as described in the fifth embodiment. With such a structure that the dummy contact plugs 5i to 5l are juxtaposed as a plurality of columnar conductors, however, each buried opening is narrowed and the burying insufficiency is caused with difficulty during the formation of the dummy contact plugs 5i to 5l. Accordingly, there is a small possibility that a foreign substance might enter the dummy contact plugs 5i to 5l.

### Eighth Embodiment

The present embodiment is a variant of the semiconductor device according to the seventh embodiment. The dummy contact plugs 5i to 5l in FIGS. 30 and 31 are replaced with a plurality of wall-shaped conductors juxtaposed to interpose a resistor 30 therebetween. Furthermore, a hollow portion is provided in a part of the wall-shaped conductors and a part of a first or second interlayer insulating film 4a or 4b is buried therein.

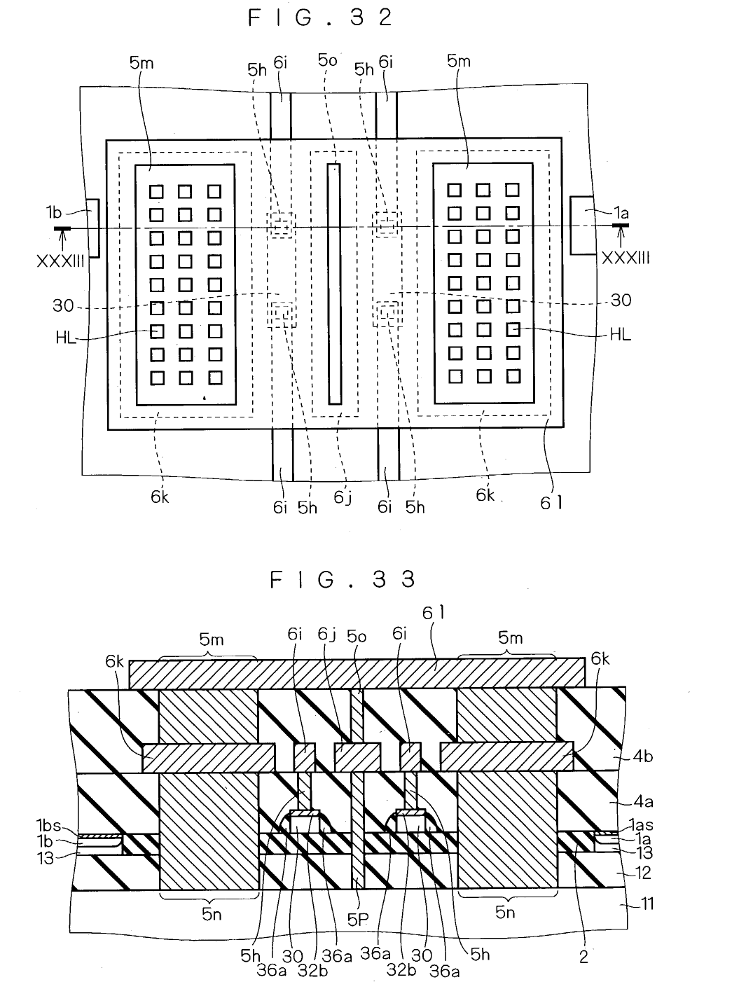

FIGS. 32 and 33 are a top view and a sectional view which show a semiconductor device according to the present embodiment, respectively. FIG. 33 is a sectional view taken along a cutting line XXXIII-XXXIII in FIG. 32.

As shown in FIGS. 32 and 33, in the semiconductor device, dummy contact plugs 5m to 5p to be the wall-shaped conductors are formed in place of the dummy contact plugs 5i to 5l to be the columnar conductors in FIGS. 30 and 31.

The dummy contact plugs 5n and 5p penetrate through the first interlayer insulating film 4a, a buried insulating film 12 and an isolating region 2 formed in a silicon layer 13. Moreover, the dummy contact plugs 5n and 5p are juxtaposed to interpose the resistor 30 therebetween. The dummy contact plugs 5m and 5o are also juxtaposed to interpose the resistor 30 therebetween.

Moreover, the dummy contact plugs 5n and 5p are connected to dummy wirings 6k and 6j provided on the first interlayer insulating film 4a, and the other dummy contact plugs 5m and 5o are connected to the dummy wirings 6k and 6j in the second interlayer insulating film 4b, respectively. A dummy wiring 6l is connected to the dummy contact plugs 5m and 5o over the second interlayer insulating film 4b. It is preferable that the dummy contact plugs 5m to 5p should also be formed by tungsten plug, for example, in the same manner as the contact plug 5h.

In the present embodiment, a plurality of hollow portions HL are provided in the dummy contact plugs 5m and 5n as shown in FIG. 32. A part of the first or second interlayer insulating film 4a or 4b is buried in the hollow portions HL. Since other structures are the same as those of the semiconductor device according to the seventh embodiment, description will be omitted.

In the semiconductor device according to the present embodiment, the dummy contact plugs 5m to 5p comprise a plurality of wall-shaped conductors and are juxtaposed to interpose the resistor 30 therebetween. Accordingly, it is possible to more reliably prevent a hydrogen atom from entering the resistor 30 as compared with the case of the columnar conductor according to the seventh embodiment.

Moreover, the hollow portion HL is provided in the dummy contact plugs 5m and 5n, and a part of the first or second interlayer insulating film 4a or 4b is buried therein. Consequently, it is preferable that a conductive film should be buried in only a portion surrounding the hollow portion HL. Therefore, a burying insufficiency is caused with difficulty during the formation of the dummy contact plugs 5m and 5n. Accordingly, it is possible to reduce a possibility that a foreign substance might enter the dummy contact plugs 5m and 5n.

### Ninth Embodiment

The present embodiment is a variant of the semiconductor devices according to the seventh and eighth embodiments, and a dummy contact plug to be connected to a wiring 6i reaching a resistor 30 is further formed in a position in which the resistor 30 is not covered in the vicinity thereof.

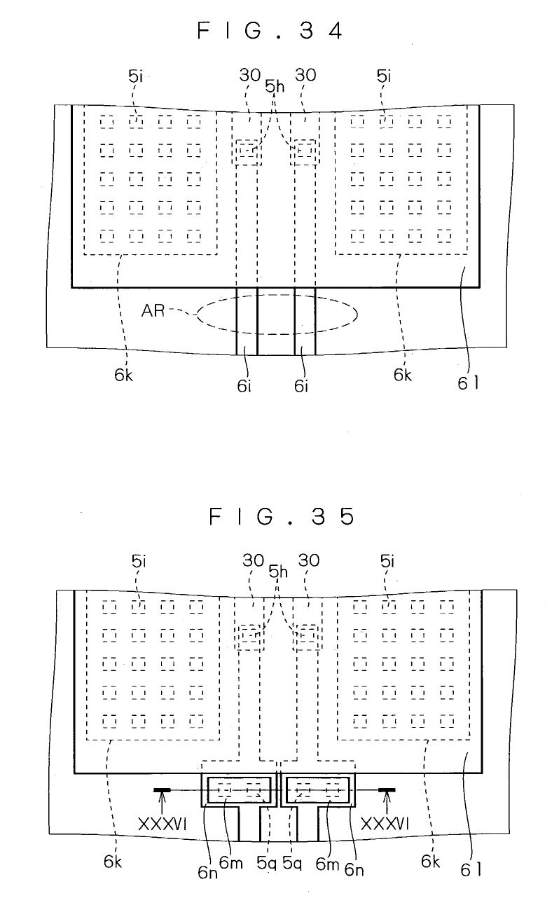

FIG. 34 is a view showing a problem of the semiconductor device according to the seventh embodiment. In the case of the semiconductor device according to the seventh embodiment, the dummy contact plugs 5i to 5l and the dummy wirings 6j and 6k are formed in the regions interposing the resistor 30 therebetween, and the dummy wiring 6l is formed above the resistor 30. Accordingly, it is possible to prevent a hydrogen atom from entering the resistor 30 in those directions.

However, the dummy contact plug is not provided in a region in which the wiring 6i connected to the resistor 30 through a contact plug 5h is led out as in a region AR of FIG. 34. Therefore, there is a possibility that the hydrogen atom might enter the resistor 30 from this portion.

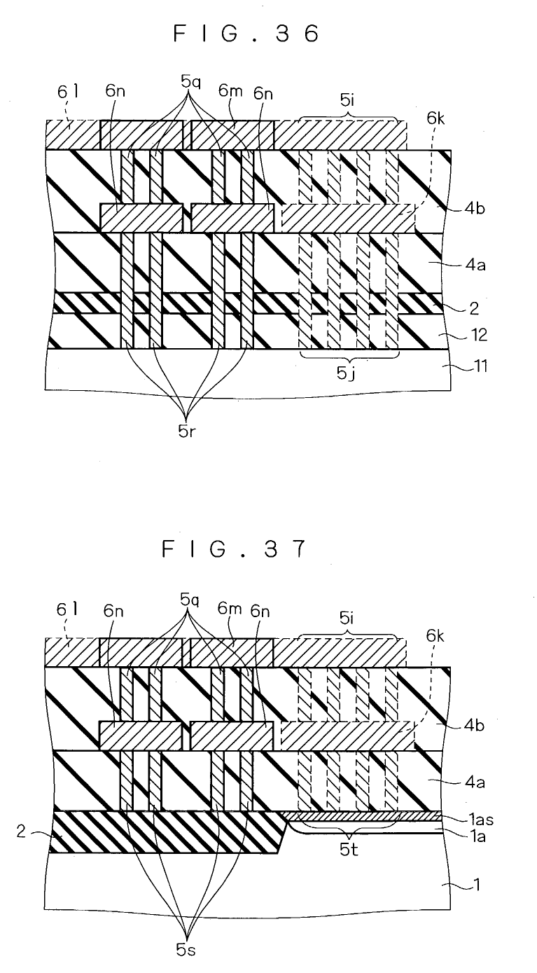

For this reason, in the present embodiment, a dummy contact plug to be connected to a wiring provided above the resistor 30 is formed in this region. FIGS. 35 and 36 are a top view and a sectional view which show the semiconductor device according to the present embodiment, respectively. FIG. 36 is a sectional view taken along a cutting line XXXVI-XXXVI in FIG. 35.

As shown in FIGS. 35 and 36, in the semiconductor device, a shape of a wiring 6n connected to the contact plug 5h provided above the resistor 30 is enlarged in the vicinity of a terminated portion of the dummy wiring 6l (that is, a position of the led portion of the wiring 6i in which the resistor 30 is not covered), and dummy contact plugs 5q and 5r are further formed in that portion. The dummy contact plug 5q is formed on a wiring 6n in a second interlayer insulating film 4b. Moreover, the dummy contact plug 5r is formed to penetrate through a first interlayer insulating film 4a, a buried insulating film 12 and an isolating region 2 formed in a silicon layer 13. A dummy wiring 6m connected to the dummy contact plug 5q is also formed on the second interlayer insulating film 4b.

It is preferable that the dummy contact plugs 5q and 5r should be formed by a tungsten plug, for example, in the same manner as the contact plug 5h. Moreover, it is preferable that the dummy wiring 6m should be formed by an aluminum wiring, for example, in the same manner as the wiring 6n.

According to the semiconductor device of the present embodiment, the dummy contact plugs 5q and 5r connected to the wiring 6n reaching the resistor 30 are formed by a different material from a material of the first and second interlayer insulating films 4a and 4b in a position in which the resistor 30 is not covered in the vicinity thereof. Accordingly, the dummy contact plugs 5q and 5r can prevent a hydrogen atom from entering the resistor. Consequently, it is possible to more reliably prevent the hydrogen atom from entering the resistor 30 in a direction in which the wiring 6n is extended. Thus, it is possible to obtain a semiconductor device in which a resistance value of the resistor 30 formed by a silicon film is changed with difficulty.

If the dummy contact plugs 5q and 5r are formed of metal, the function of preventing the hydrogen atom from entering the resistor 30 can be more enhanced. Moreover, since the metal is used for the material, the dummy contact plugs 5q and 5r can be formed easily.

U.S. Pat. No. 5,530,418 has disclosed the invention having a structure which is similar to the top view of FIG. 34 and employs a bulk substrate in place of an SOI substrate. The present embodiment can also be applied to such a structure.

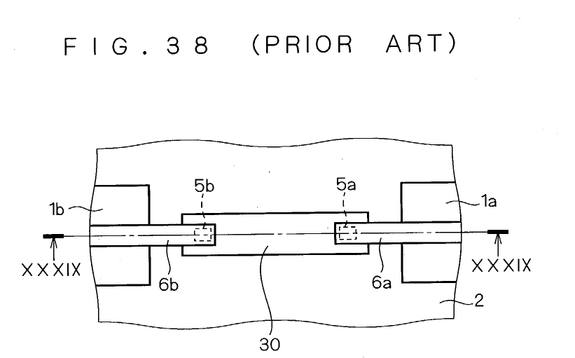

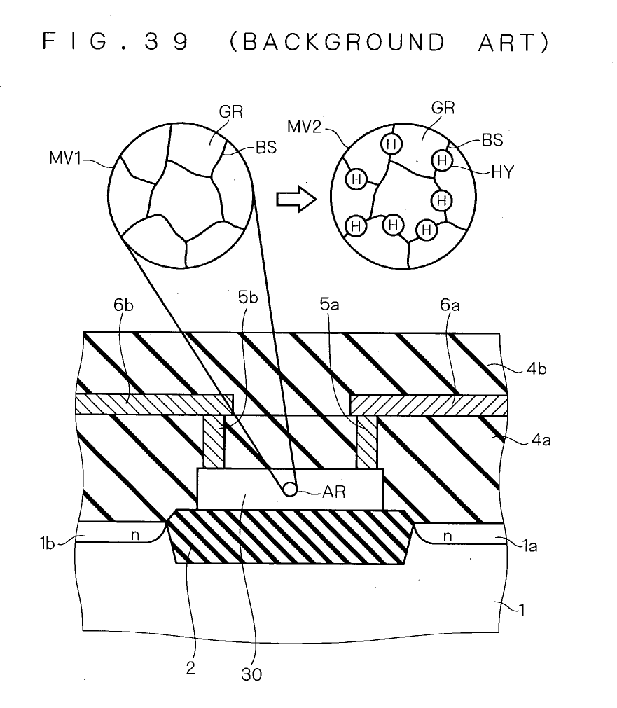

FIG. 37 is a sectional view showing a variant of the semiconductor device according to the present embodiment. In FIG. 37, a semiconductor substrate 1 to be a bulk substrate is employed in place of the SOI substrate in FIG. 36. An isolating region 2 and an active region 1a are formed in the semiconductor substrate 1. A silicide 1as is also formed on a surface of the active region 1a.

Since the bulk substrate is employed, a dummy contact plug 5s is formed in contact with the isolating region 2 in the first interlayer insulating film 4a in place of the dummy contact plug 5r penetrating through the first interlayer insulating film 4a, the buried insulating film 12 and the isolating region 2. Moreover, a dummy contact plug 5t is formed in contact with the silicide 1as in the first interlayer insulating film 4a in place of the dummy contact plug 5j penetrating through the first interlayer insulating film 4a, the buried insulating film 12 and the isolating region 2 in the same manner. Since other structures are the same as those of FIG. 36, description will be omitted.

With such a structure, similarly, the dummy contact plugs 5q and 5s to be connected to the wiring 6n reaching the resistor 30 more reliably prevent the hydrogen atom from entering the resistor 30 in the direction in which the wiring 6n is extended. Accordingly, it is possible to obtain a semiconductor device in which a resistance value of the resistor 30 formed by a silicon film is changed with difficulty.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising a resistor formed by a silicon film,
wherein at least a surface portion of said resistor is amorphous silicon, and
a silicide is formed in a connecting portion of a contact plug in said surface portion.

2. A semiconductor device comprising:
a resistor formed by a silicon film; and
a silicon germanium film provided in contact with said resistor.

3. A semiconductor device comprising:
a resistor formed by a silicon film;
an interlayer insulating film covering said resistor; and
a dummy contact plug formed by a different material from a material of said interlayer insulating film, insulated from said resistor and covering at least a part of an upper portion of said resistor,
wherein said different material has the function of preventing a hydrogen atom from entering said resistor.

4. The semiconductor device according to claim 3,
wherein said dummy contact plug is formed of metal.

5. The semiconductor device according to claim 3,
further comprising a dummy wiring formed by a different material from a material of said interlayer insulating film and provided on said dummy contact plug,
wherein said different material has the function of preventing a hydrogen atom from entering said resistor.

6. The semiconductor device according to claim 5,
wherein said dummy wiring is formed of metal.

7. The semiconductor device according to claim 3,
wherein a part of said interlayer insulating film is buried in said dummy contact plug.

8. A semiconductor device comprising:
an SOI (Silicon On Insulator) substrate including a laminating structure having a support substrate, a buried insulating film and a silicon layer;
a resistor provided on said SOI substrate and formed by a silicon film;
an interlayer insulating film covering said resistor; and
a dummy contact plug formed by a different material from a material of said interlayer insulating film in the vicinity of said resistor and penetrating through said buried insulating film and an isolating region formed in said silicon layer,
wherein said different material has the function of preventing a hydrogen atom from entering said resistor.

9. The semiconductor device according to claim 8,
wherein said dummy contact plug is formed of metal.

10. The semiconductor device according to claim 8, further comprising
a dummy wiring formed by a different material from said material of said interlayer insulating film and covering a portion above said resistor,
wherein said different material has the function of preventing a hydrogen atom from entering said resistor.

11. The semiconductor device according to claim 10,
wherein said dummy wiring is formed of metal.

12. The semiconductor device according to claim 8,
wherein said dummy contact plug comprises a plurality of columnar conductors which are juxtaposed.

13. The semiconductor device according to claim 8,
wherein said dummy contact plug comprises a plurality of wall-shaped conductors which are juxtaposed to interpose said resistor therebetween, and
a part of said interlayer insulating film is buried in a part or all of said wall-shaped conductors.

14. A semiconductor device comprising:
a resistor formed by a silicon film;
an interlayer insulating film covering said resistor;
a contact plug formed by a different material from a material of said interlayer insulating film and connected to said resistor;
a wiring formed by a different material from said material of said interlayer insulating film and connected to said contact plug; and
a dummy contact plug formed by a different material from said material of said interlayer insulating film and connected to said wiring in a position in which said resistor is not covered in the vicinity thereof,
wherein said different material has the function of preventing a hydrogen atom from entering said resistor.

15. The semiconductor device according to claim 14,
wherein said dummy contact plug is formed of metal.
